(19) United States
(12) Patent Application Publication
(10) Pub. No.: US 2009/0098280 A1
(43) Pub. Date: Apr. 16, 2009

(54) VAPOR DEPOSITION APPARATUS AND METHOD OF VAPOR DEPOSITION MAKING USE THEREOF

(76) Inventor: Jean-Pierre Tahon, Langdorp (BE)

Correspondence Address: NEXSEN PRUET, LLC, P.O. BOX 10648, GREENVILLE, SC, 29603, US

(21) Appl. No.: 11/871,272

(22) Filed: Oct. 12, 2007

(51) Int. Cl. B05D 5/06; C23C 16/00

(52) U.S. Cl. 427/69; 118/726

(57) ABSTRACT

A vapor deposition apparatus comprises as a vaporization assembly a container in form of a boat or crucible and a support for vapor depositing phosphor or scintillator material thereupon from raw materials present in said container, wherein said boat or crucible internally comprises an assembly of two perforated covers or lids, one of which is an outer lid (also called first lid) more close to the said support and the other cover is an inner lid (also called second lid) more close to the bottom of the said crucible; and wherein perforations present in said outer lid represent a total surface exceeding the total surface of perforations present in said inner lid more close to the bottom of the said crucible and wherein in said vapor deposition apparatus the said raw materials or the bottom of the said crucible cannot be directly seen through said perforations from any point of said support; thereby providing the manufacturing of a radiation image storage phosphor layer on a support or substrate, by a vapor depositing step of raw materials of an alkali metal halide salt and a lanthanide dopant salt or a combination thereof in order to ensure vapor deposition of a binderless needle-shaped storage phosphor layer in the said vapor deposition apparatus, so that a ratio between the total surface of perforations in said inner lid more close to the bottom of crucible and the total surface of perforations in said outer lid more close to the support is not more than 1.0.

### FIELD OF THE INVENTION

The present invention relates to a vapor deposition apparatus providing homogeneous deposition onto a substrate or support, mounted therein, of phosphor or scintillator materials from raw materials present in heated crucible(s), thereby, besides avoiding “spot errors” or “pits” resulting in uneven deposit due to spitting of liquefied raw materials, provoking a more constant deposition velocity onto said substrate, without influencing the substrate temperature.

### BACKGROUND OF THE INVENTION

In physical vapor deposition (PVD) as well as in chemical vapor deposition (CVD) techniques, factors providing deposition of homogeneous phosphor or scintillator coating compositions and homogeneous layer thicknesses over the entire surface thereof, besides use of especially designed electrically heated crucible(s), are related with the distance determining the profile of the vapor cloud at the position of the substrate, as has e.g. been described in US-A 2004/0219289.

As disclosed in U.S. Ser. No. 60/839,339 a method of manufacturing a radiation image storage phosphor layer on a support or substrate comprises a vapor depositing step of raw materials of an alkali metal halide salt and a lanthanide dopant salt or a combination thereof in order to ensure vapor deposition of a binderless storage phosphor layer from one or more resistance-heated crucible(s) in a vapor deposition apparatus, wherein one or more shutter(s) are positioned between said crucible(s) and said support or substrate, and wherein at the time said vapor depositing step starts while opening a shutter, a start temperature is measured on and registered by means of a thermocouple positioned close to the support at the back side of the support, opposite to the side of the support where vapor becomes deposited, is less than 250° C., but not less than 100° C., when an additional heating is applied. In a more particular embodiment said start temperature as measured on and registered by means of a thermocouple positioned close to the back side of the support, opposite to the side of the support where vapor becomes deposited, is less than 220° C., but not less than 130° C., when an additional heating, provided by means of resistive heating or radiation heating, is applied.

As an advantageous effect of that invention it has been established, as set forth above in the description and in the examples thereof, that in the conditions within a temperature range of less than 250° C., but not less than 100° C., measured on and registered by means of a thermocouple at the back side of the support where no raw materials become deposited, while starting vaporization by opening the shutters of crucibles in a resistive heating evaporation process, that an optimized speed and sharpness is measured for the storage phosphor plate thus obtained, when an additional heating is applied.

However both measures in favor of homogeneous deposit of the desired phosphor or scintillator material, more particularly with respect to the steering and the control of the temperature at the front as well as at the back side of the support, are rather complicated.

Anyhow in any evaporation process care should be taken in order to avoid “spot errors” or “pits”, resulting in uneven deposit of phosphors or scintillators, due to spitting of the liquefied raw materials present in heated containers: besides physical presence of an undesired unevenness at the surface, differences in speed or sensitivity may lay burden on its use as a screen, plate or panel for diagnostic imaging, especially when those phosphors are suitable for use in direct radiography as scintillators, in intensifying screens as prompt emitting phosphors or in storage panels as stimulable phosphors, used in computed radiography (CR).

Undesired growth of the needles in interstices should moreover be avoided. Presence of an excess of large “spot errors” or “pits” and, more particularly of “interstitial needle growth between the needles grown on the support” moreover has a negative influence on image sharpness as expressed by MTF data, so that an improvement thereof is highly requested.

### OBJECTS AND SUMMARY OF THE INVENTION

Therefore it is an object of the present invention to provide a simple vapor deposition apparatus, allowing manufacturing of screens, panels or plates with a homogeneous deposit of desired phosphor or scintillator compositions, moreover providing an increased image definition or sharpness as expressed by MTF measurements.

It is another object of the present invention to avoid “interstitial growth of needles” in the gaps or interstices between needles while vapor depositing, in order to avoid loss of crystalline homogeneity in the needle-shaped phosphor or scintillator layer of the screen or panel.

Still a further object of the present invention remains to provide a simple construction as a tool in order to prevent undesired “spots” or “pits” from reaching the substrate or support for phosphors or scintillators to be prepared while applying CDV or PDV techniques, especially in vacuum conditions in a vacuum chamber wherein vaporization and deposit of said scintillator or phosphor material on a substrate is envisaged.

The above-mentioned advantageous effects are realized by making use of a particular vapor deposition apparatus comprising a container in form of a boat or crucible for the raw materials to become vaporized and to become deposited onto a substrate or support mounted in said vapor deposition apparatus, wherein said container is provided with an assembly of perforated covers or lids, internally mounted in the crucible, from which vaporized raw materials escape while heating said container and wherein said assembly has the specific features set out in claim 1. Specific features for preferred embodiments of the invention are set out in the dependent claims.

Further advantages and embodiments of the present invention will become apparent from the following description.

### BRIEF DESCRIPTION OF THE DRAWINGS

FIG. 1 shows a view of a crucible with an indication of the significance of dimensions as “width ‘W’”, “height ‘H’” and “length ‘L’”, wherein (1) represents a folded crucible; (2) the container of the crucible, (3) a lip (present at both sides of the crucible), (4) a cover plate with (5) a slit therein, so that the incident angle of the vapor of the stimulable phosphor with the normal line of the light reflection surface of the substrate was made to 20° or less, wherein guiding plate (6), further directs the vapor stream towards the substrate. It is clear that width ‘W’ is always less than length ‘L’. One long slit, whether or (normally) not interrupted at regular sites, is arranged parallel with the longest side or length of the crucible. The slit (5) is optionally provided with an insulating member at the borders, in order to avoid loss of heat at the slit opening by conduction through the metal of the cover plate (4).

FIG. 2 shows a side view (cut through position A from FIG. 1)

FIG. 3 shows a front view (cut through position B from FIG. 1)

FIG. 4 shows a side view (cut through position A) for a crucible configuration with internally positioned folded perforated cover plates (7) and (8), representing the outer or first cover or lid (8) and the inner or second cover or lid (7) respectively.

FIG. 5 shows a front view (cut through position B) for the same crucible configuration as in FIG. 4, with internally positioned same folded perforated cover plates (7) and (8).

FIG. 6 shows MTF at 1 lp/mm as a function of the ratio between total surface of the perforated inner (second) lid (7)—more close to the bottom of crucible (2)—and total surface of the perforated outer (first) lid (8)—more close to the support.

FIG. 7 shows MTF at 3 lp/mm as a function of the ratio between total surface of the perforated inner (second) lid (7)—more close to the bottom of crucible (2)—and total surface of the perforated outer (first) lid (8)—more close to the support.

FIG. 8 shows some examples of perforated covers used in the experiments.

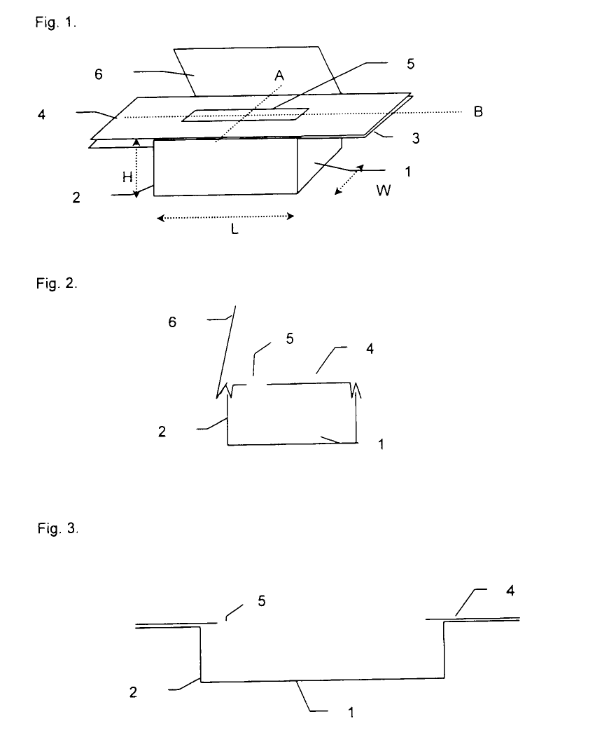

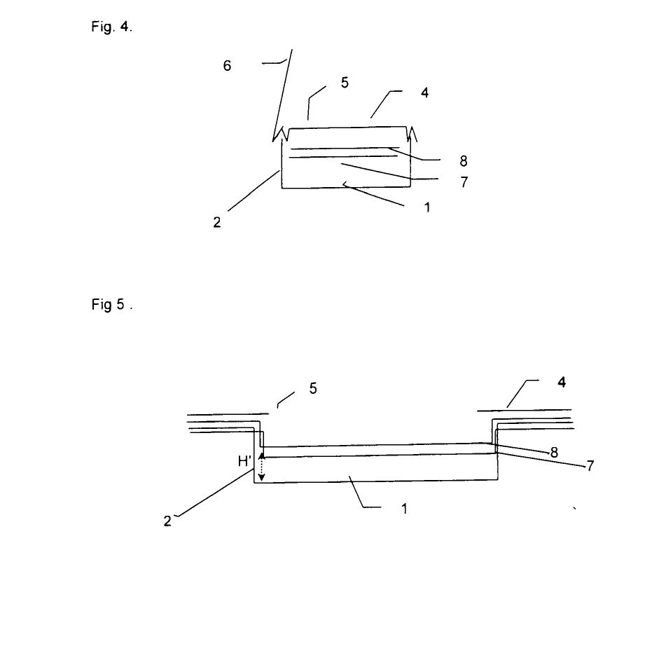

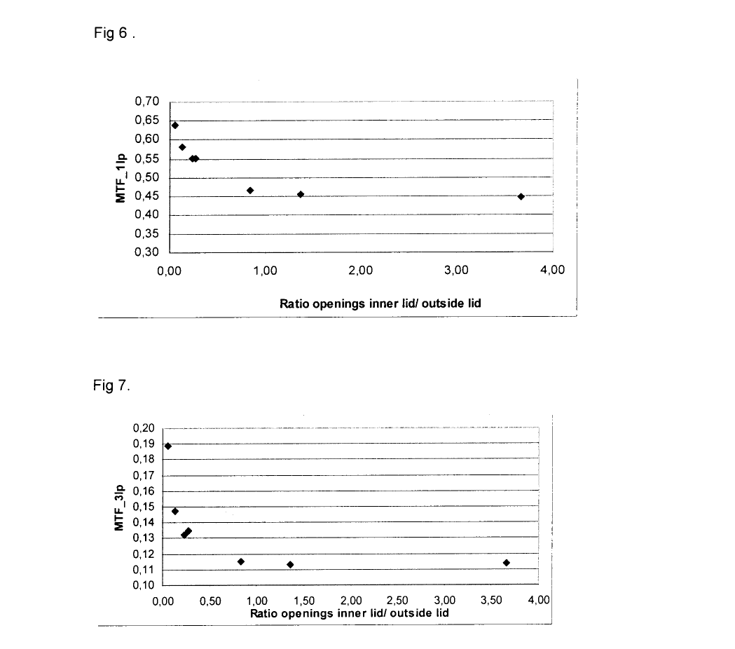

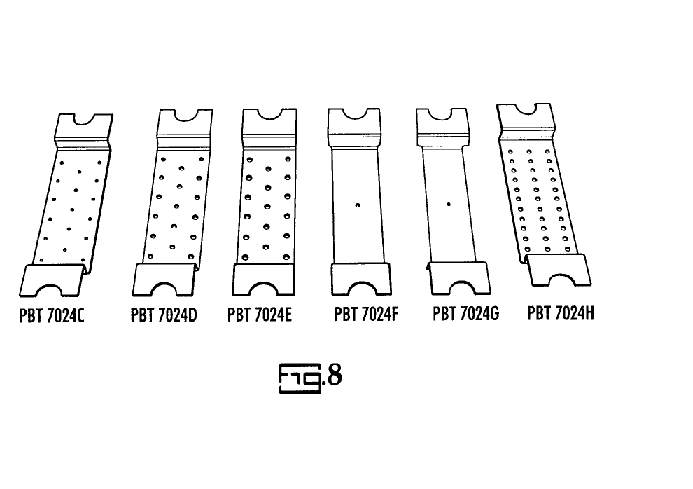

### DETAILED DESCRIPTION OF THE INVENTION

In a vapor deposition apparatus according to the present invention, as a vaporization assembly, a container in form of a boat or crucible is provided, said boat or crucible having a bottom and side walls, and a support or substrate for vapor depositing phosphor or scintillator material in form of a layer thereupon, from vaporized raw materials present in said container, wherein said container internally comprises an assembly of at least two covers or lids having one or more perforations, one of which is an outer lid as a first lid more close to the said support and the other cover is an inner lid as a second lid more close to the bottom of the said boat or crucible; wherein perforations in said outer lid represent a total surface exceeding the total surface of perforations of the said inner lid more close to the bottom of the said boat or crucible, and wherein in said vapor deposition apparatus said raw materials or the bottom of the said crucible can never be directly seen through said perforations from any point of said support.

Distances between both lids or covers are variable from one vaporization process to the other, in that the said distances depend on the amount of raw materials that should be evaporated, present in crucible. Positioning of both covers, relative to each other and to the surface level of the raw materials, thus depends on the amount of raw materials present at the start of the vaporization process. More particularly raw materials are normally not filling the crucible up to a level of more than 80% of the crucible height, measured from the bottom up to the position of the outer or first lid, whereas the second or inner lid is positioned under the first lid within a distance ranging from 2% up to 40% of the said crucible height. Whereas the said 40% level of the said crucible height for the second lid means that the inner lid is in contact with the liquefied raw materials at the start of the evaporation process, it is however not excluded, but not recommended, to optionally have liquefied material positioned above the position of the inner lid at the start of the vapor deposition process. In that optional case it is recommended however that the level of the liquefied raw materials remaining in the crucible while evaporating, sinks beneath the position of the inner lid as soon as possible, i.e. at least within half a time of the total vaporization time or cycle. In a particular embodiment the crucible is provided with a closing cover, i.e. a cover without openings positioned on top of the crucible, until the vapor deposition process effectively starts.

One way to avoid spots to reach the web, substrate or support commonly known as being composed of a (soda-lime, quartz, sapphire) glass sheet, a metal sheet such as aluminum, iron, tin, chromium, etc., whether or not covered with an oxide layer or e.g. a (silver) mirror layer optionally in combination with an organic coating, an amorphous carbon (a-C) sheet, a carbon fiber reinforced sheet or a heat-resistant resin such as aramide, in the case of a gas phase deposition of a phosphor layer formed thereupon, is to cover the container comprising a tray, boat or crucible onto its outlet with a metallic raster, supported by the surrounding edges of the crucible and covering, at least in part, said crucible.

It is clear that such material composition of the perforated cover or covers as well as of the container should be resistant to physical influences, in that the materials should be refractory materials. Desired refractory materials are chosen therefore and are selected from the group of materials consisting of Mo, Nb, Ta and W. An ultimate choice of a material suitable for use as a refractory cover material most generally depends on its handling ability as the cover should be brought into the desired form (e.g. deformation by folding or bending of plates of the desired thickness in a so-called “nip-zone” or between rollers or other “flattening means” or “bending means”) in order to be suitable for use as a cover onto a container, boat or crucible or, optionally, into the chimney thereof, in order to attenuate escape of vaporized raw materials and in order to provide controlled homogeneous deposit onto the substrate or support of the phosphor or scintillator screen or panel that should become manufactured.

It is moreover clear that only the raw material(s) present in the container should melt at the designed high process temperatures (in the range up to 700-900° C.) in order to become vaporized and deposited afterwards onto a substrate support. Formation of e.g. “mixed melt” crystals composed of crucible material and raw materials contained in the crucibles should clearly not be appreciated, as presence of crucible material in deposited layers would form a source of undesired contamination and, optionally, coloration. Besides being physically inert, it is clear that the cover material as well as the crucible material should be chemically inert to an extent as much as possible, in that chemical reactions between contacting raw materials and crucible materials should be about impossible, as otherwise the composition of the deposited product onto the substrate of the screen or panel would not be well-defined. Besides such an “undefined” composition, homogeneity or uniformity of the deposited layers should be moreover out of control.

Different configurations are available in order to get the most advantageous solution in order to avoid those spot defects. Even when very small holes are present in a cover, said cover being present as a last barrier in the crucible where vaporized raw materials pass before entering the space in the vapor deposition apparatus between container and support, an excess of “spot errors” or “pits” can still disturb the uniformity of the pattern of the deposited layer. A solution has been found now to be attained by providing an assembly of perforated covers present in the crucible having a bottom and surrounding side walls, wherein a total surface of perforations of the perforated second cover or inner lid more close to the substrate or support, equals or exceeds the total surface of perforations of the perforated cover more close to the bottom of the crucible. In one embodiment thereof the said inner lid is positioned on top of the liquefied raw materials, i.e. in contact therewith. Such a configuration results in a slower vapor deposition, i.e. deposition of lower amounts of phosphor or scintillator material per minute and a more easy maintenance of the substrate temperature while less additional deposition energy in form of heat reaches the substrate support. Moreover mounting of both perforated covers in the crucible so that their perforation patterns never overlap, i.e. so that the bottom of the crucible cannot be seen or observed from not any point of the substrate or support, results in absence of undesired spot errors or pits onto that support while performing vaporization. Even more important however and as a particularly advantageous effect of the present invention, it has unexpectedly been found now that, as a consequence of the use of such a perforated cover assembly, the decreased temperature change of the support as measured by a thermocouple positioned close onto the back side of said support, results in an increased sharpness as measured in MFT percentages.

Configurations of subsequent perforated covers, forming an assembly of the crucible, wherein one of which is present at a position more close to the support and which has a total opening or summoned hole surface larger than the one more close to the raw materials on the bottom of the crucible, can be provided in different ways.

So in one embodiment the holes or small slits forming perforations in both covers may be identical or different in shape, such as in form of an ellipse, a circle, a triangle, a square, a rectangle, a hexagon (e.g. in form of honeycombs) or another polygon or even an undefined form, without however being limited hereto. In another embodiment said small holes or slits, present as perforations in both covers may be identical or not with respect to the surface that they each represent. A combination of holes or small slits as perforations may be provided wherein the form or shape is the same, whereas the surface of each of them is different; wherein the form or shape is different, whereas the surface of each of them is the same or wherein both the form or shape and the surface of each of them are different. Both required conditions as mentioned hereinbefore should however ever be fulfilled, i.e., no overlap between perforations in subsequent perforated covers and a larger total surface of perforations for the perforated cover more close to the support of the screen or panel upon which the phosphor or scintillator layer should become vapor deposited. In one particular embodiment the perforated cover more close to the support has more perforations representing a smaller lid surface each. In another embodiment the perforated cover more close to the support has less perforations representing a larger surface each, than the cover located more close to the bottom of the crucible. Restrictions with respect those embodiments, i.e. with respect to the perforation pattern in the assembly of perforated covers clearly depends on the additional requirement not to have any overlap between the perforations as set out hereinbefore.

It is understood to be most advantageous that in case of two perforated plates or covers, that these plates or covers are mounted as parallel covers. So in one embodiment in the vapor deposition apparatus according to the present invention, said inner and said outer lid are mounted parallel versus each other in said container. More particularly said inner and said outer lid are mounted parallel versus the bottom of the crucible or versus a plane tangent to the bottom if the said bottom would not be flat, or to the surface of the liquefied raw materials. In another embodiment said inner and said outer lid are mounted parallel versus each other but not parallel versus the bottom of the crucible or versus a plane tangent to the bottom or to the surface of the liquefied raw materials. In still another embodiment said inner and said outer lid are not mounted parallel versus each, but one of those two lids is positioned parallel versus the bottom of the crucible or versus a plane tangent to the bottom or versus the surface of the liquefied raw materials. And in still another embodiment none of said inner lid, said outer lid or the plane of the bottom of the crucible or the plane tangent to the said bottom or the surface of the liquefied raw materials is parallel versus each other. The most important condition remains that in the vapor deposition apparatus of the present invention the bottom of the said crucible can never be directly seen through said perforations from any point of said support.

More particularly the vapor deposition apparatus according to the present invention advantageously has perforations in said inner and said outer lid having equivalent circular diameters in the range of 1 mm up to 5 mm, with an average distance between centers of the said holes in the range from 2 mm up to 10 mm. The terms “equivalent circular diameters” and “equivalent circles” have been introduced in order to allow each perforation shape and to define the dimensions of the perforations and distances between perforations in a way, independent on that shape. So the term “equivalent circular diameter” refers to a surface of whatever a perforation, expressed as its equivalent surface of a circle, from which the diameter is calculated. From the same equivalent circular surfaces, the centers are taken in order to express average distances between perforations. So e.g. perforations having a larger size in the centre and a smaller size in the vicinity of the side walls of the crucible for the perforated cover more close to the support and vice versa for the perforated cover more close to bottom of the crucible may be advantageous in the configuration of the cover assembly in the vapor deposition apparatus of the present invention.

In one embodiment in the vapor deposition apparatus according to the present invention, every distance between said inner and said outer lid is feasible, and the second or inner lid, more close to the bottom of the crucible, is advantageously not positioned into the liquefied raw materials. In another embodiment in the vapor deposition apparatus according to the present invention, every distance between said inner and said outer lid is feasible, but it is not excluded that, optionally, the second or inner lid more close to the bottom of the crucible is positioned into the liquefied raw materials, provided that it does not remain positioned into the said liquefied raw materials for a period of time of more than 50% of the total evaporation time.

In the vapor deposition apparatus according to the present invention shortest distances between perforated plates or covers in the assembly are in the range of 2% up to 40% of the total height of the inner crucible wall perpendicularly measured from top to bottom. In another embodiment according to the present invention, the perforated cover assembly is constructed so that said perforations are identical for both plates. In still another embodiment according to the present invention, the assembly is constructed so that said perforations are differing for both of the two perforated plates, in that the plate more close to the support has more and smaller perforations representing a total surface which is larger than that of the perforated cover more close to the bottom of the crucible container, i.e. to the surface of the raw materials which should be vapor deposited.

In an even further embodiment of the perforated cover assembly in the vapor deposition apparatus according to the present invention perforations said cover has differing perforation dimensions within one cover, in that a larger size in the centre and smaller sizes in the vicinity of the side walls of the perforated cover more close to the support are provided and vice versa for the perforated plate positioned more close to the bottom of the crucible. It is not excluded to provide even more than two perforated covers inside the crucible. So e.g. for a third cover present at a distance even more close to the bottom of the said crucible, i.e. thus even farther from the substrate or support than the other two perforated covers, there is no restriction with respect to the perforation pattern, provided that the said other two perforated covers have properties as disclosed according to the present invention.

In the vapor deposition apparatus according to the present invention, said assembly of two covers or lids and said crucible is composed of the same or differing refractory materials, and wherein said refractory materials are metal or metal alloys selected from the group consisting of tantalum (Ta), molybdenum (Mo), niobium (Nb), tungsten (W) and heat-resistant stainless steel. It is not excluded to get vapor deposited needles, colored to a certain degree as a consequence of formation of compounds consisting of said refractory materials and halides of the raw material compositions as has e.g. been described in U.S. Pat. No. 6,977,385. Said refractory materials advantageously have the same or a differing composition for the crucible and for the perforated cover assembly. In favor of good, i.e. uniform, heat conducting properties, it is advantageous to have the same composition for the walls of the crucible and the perforated covers, mounted therein, as it has been established that said good heat conducting properties, e.g. by resistive, induction or radiation heating of the crucible container, avoid occurrence of undesired deposit of raw material onto the side walls of the crucible or onto the inner sides of the covers or perforation holes or slits before allowing escape of raw material in form of a vapor cloud from the vaporization crucible. It is favorable therefor that the wall or cover temperature never sinks below the temperature of liquefied raw materials in the crucible. It may moreover even be desirable to provide an increase of the temperature inside the space between both perforated covers, e.g. by an additional resistive heating component or induction heating, thus adding energy from a position from the outside of the crucible. In the case of resistive heating this may e.g. be performed by an extra resistive heating mounted in a region between both covers, outside of the crucible or by adding radiation energy provided by e.g. infrared heaters or lamps, situated inside the crucible, i.e. in a space between both perforated covers. Induction heating may require presence of thicker walls of the crucibles, in favor of a more inert vaporization system, thus providing an even better control ability of the vapor deposition process. Combination of differing additional energy sources may even be applied. This measure is fully in accordance with the disclosure in US-Application 2007/0098880. An additional advantage offered by presence of lamps into the space between both covers is that these lamps may act as baffles. Thereby more degrees of freedom with respect to the configuration of perforations in the cover more close to the support are offered, in that it will be more easy to provide a configuration wherein “no overlap” is provided as described hereinbefore.

A cover without holes or slits or any other perforation pattern, also called “non-perforated cover” as a closing cover or “slot cover”, is preferably present as a non-perforated outermost cover of the vaporization assembly, more particularly during heating. Covering the holes or slits of the perforated cover more close to the support before having brought the crucible to an optimized and constant high temperature, wherein said temperature is preferably homogeneously distributed over the whole crucible, allows to start evaporation of the raw materials in a “steady-state-flow”. Once the “slot cover” is removed, evaporation of the raw materials thus proceeds in a way in order to get a continuous and homogeneous vapor stream in the direction to the substrate support, wherein a guiding plate is advantageously provided within an evaporation or deposition chamber in the vapor deposition apparatus of the present invention, thereby guiding the vapor stream or cloud towards the substrate or support in order to more sharply define the region wherein phosphor or scintillator material should become deposited. Presence of one or more baffles between the vaporizing assembly and support advantageously restricts the vapor deposition region on the substrate to a smaller segment or sector, and avoids undesired deposition and loss of scintillator or phosphor material as e.g. on the wall of the deposition chamber of the vapor deposition apparatus. A depletion or exhaustion of the raw materials present in the crucible may be avoided by starting vaporization from high enough a filling rate of the raw materials in the boat of at least 40% or by providing a replenishment unit to the vapor deposition apparatus. This may e.g. be performed as described in US-Application 2007/0104864, i.e. by transferring such particulate material through the feed opening along a feeding path to a vaporization zone. In another embodiment the shape of the folded boat or crucible may be altered, in that the vapor deposition boat may be folded in an L-shape, so that in that L-shaped part the depth of a container portion of a bottom plate is increased in order to have more raw materials in the container.

Especially in vacuum deposition processes, i.e. at very low pressures as e.g. in the range from 10⁻⁵ to 1 Pa, throughout said vapor deposition process, vaporized raw materials may escape from the liquefied or molten raw material mixture in an uncontrolled way, at a rate in the range from several tenths of meters per second, up to even hundreds of meters per second. By making use of an arrangement of perforated covers according to the present invention as described hereinbefore, wherein the total surface, represented by the cover perforations increases as the distance from the corresponding cover to the substrate or support decreases, the velocity with which deposit onto the support is formed is remarkably attenuated, changes in temperature of the substrate while performing vapor deposition are minimized and sharpness of the deposited phosphor or scintillator layer thus formed, as measured from MTF-measurements at 1 lp/mm and 3 lp/mm, increases.

All of those measures moreover avoid, at least in part, presence of a “sub-layer” between support and needle-shaped phosphor layer while starting vaporization, in that an “amorphous” interlayer may appear to a considerably reduced extent if compared e.g. with the descriptions in U.S. Pat. Nos. 6,967,339 and 7,161,160. The same can be said with respect to the optional presence of a needle-shaped CsBr-sublayer as in U.S. Pat. No. 7,193,235 which may be present but in that case only grows to a considerably reduced extent. Presence of such an interlayer, even up to a reduced extent, may be in favor of adhesion between anodized aluminum support and needle-shaped phosphor layer. It may even be more advantageous to apply an organic coating, optionally provided with incorporated dyes or pigments, in order to improve the adhesion between the support and the needle-shaped phosphor layers. In still another embodiment at the end of vaporization it is recommended to let the crucible exhaust from raw materials as a sudden stop by putting a slot cover without perforations onto the perforated covers while vaporizing may however cause pits and spot errors having an unpredictable crystal form and composition. Alternatively in favor of adhesion a plasma treatment may be given to the support. Adhesion of the phosphor layer onto the support may also be provided by an oxide layer onto the support, as e.g. by anodic oxidation, onto a metal support or substrate, preferably having a thickness in the order of 0.005 up to 1 μm. In direct contact with the support and as an interlayer between support and phosphor layer a reflecting mirror film may be provided in favor of speed. In favor of homogeneously distributed dopant or activator, the termal conductivity of the support should e.g. be in the range of from 0.1 to 20 W/mK as described in U.S. Pat. No. 7,193,225. A homogeneous distribution of needles, vapor deposited onto a substrate may further be provided while starting from a structured substrate or support.

As a result of those particular measures with respect to the perforation configuration of the perforated covers mounted in a crucible of a vapor deposition apparatus according to the present invention, changes in vapor deposition conditions while performing said deposition are minimized, the substrate or support temperature changes more slowly and the dimensions of anisotropically grown crystals in form of needles are characterized by a more uniform crystallinity. Less changes in the smaller, more uniform diameters of the needles moreover means that more space between the thinner needles becomes available, as well as a lower packing density of the needles, as well as less “cross-talk” between the needles and a decreased tendency of cracking in the phosphor layer. This results in a better image definition or sharpness, expressed as higher MTF percentages, according to the objects of the present invention as envisaged.

With respect to average values of shortest distances between crucible(s) and substrate, these are known to be preferably in the range of from 10 cm to 60 cm and even more preferred from 10 cm to 30 cm. Too large a distance of e.g. more than 100 cm, leads to considerable loss of material and decreased yield of the process, whereas too small a distance of less than 10 cm, e.g. about 5 cm or even less, leads to too high a temperature of the substrate and heterogeneously deposited layers. Measures in order to avoid an increase of the temperature of the substrate have e.g. been described in U.S. Pat. No. 6,720,026. An inlet of cooled gas may however cause further atoms or molecules of said cooled gas and vaporized raw material, and, as a consequence thereof, irregularities in deposited material.

In order to improve a modulation transfer function (MTF) associated with stimulable phosphor layer having columnar crystals, a diameter size of columnar crystal is preferably 1 μm to 20 μm and is more preferably 1 μm to 10 μm. When such a columnar crystal diameter is less than 1 μm in size, MTF drops because of the scattering of stimulated emission light by the columnar crystal and when columnar crystal diameter is 20 μm or thicker in size, MTF also drops because of decline in the directivity of stimulated emission light. Moreover the diameter preferably is not more than about 12 μm when the beam of the excitation light is about 60 μm, whereas a pixel size should be at least 20 μm. Otherwise the diameter preferably is not more than about 6 μm when the beam of the excitation light is about 30 μm, whereas a pixel size should be at least 10 μm. Sharpness however remains determined by characteristics related with needle dimensions, more than by pixel sizes. The size of columnar crystal diameters as given here is an average value of diameters obtained by converting cross-sectional areas of each columnar crystal into circles through an observation of the surface of columnar crystal parallel to the plane of substrate and it is calculated, using a micrograph including at least 100 columnar crystals or more in the observed field. The average length of the needles preferably is in the range from 100 μm up to 1000 μm. For particular applications such as mammography, the average length is in the range from 100 μm up to 500 μm. Spacing between columnar crystals is preferably not more than 30 μm and is, depending on the applications, even more preferably not more than 10 μm. When spacing in length exceeds 30 μm, sensitivity drops since a filling factor of the stimulable phosphor layer declines. Spacing between respective columnar crystals is preferably not more than 30 μm, and more preferably not more than 10 μm as spacing exceeding 30 μm lowers the filling ratio of a phosphor of the phosphor layer. A recommended filling ratio is in the range from 60 to 95%, i.e. in the range from 65 to 80% for thinner phosphor layers as applied e.g. in mammographic applications and in the range from 75 to 90% for thicker, more sensitive layers in applications such as e.g. chest radiography. More particularly with respect to mammographic applications a radiation image storage panel having a stimulable phosphor layer and a light-reflecting layer provided thereupon, is built up so that the said stimulable phosphor layer scatters stimulating light and stimulated light emitted by said phosphor layer with a scattering length of 5 to 20 μm and said light-reflecting layer scatters stimulating light with a scattering length of 5 μm or less as disclosed in US-Application 2004/0104363.

Since the width of columnar-crystal is influenced by a temperature of substrate, a degree of vacuum, an incident angle of a vapor stream, and so forth, a desired width of columnar crystal can be obtained by controlling those factors.

Preferred phosphors or scintillators to become prepared as vapor deposited layers by making use of a vapor deposition apparatus as described hereinbefore are those of the alkali metal type. More in particular storage phosphors are envisaged as e.g. those that have been described in U.S. Pat. No. 5,736,069.

Such phosphors have been disclosed as having the general formula given hereinafter:

M¹⁺X·aM²⁺X′₂·bM³⁺X″₃:cZ

wherein:

M¹⁺ is at least one member selected from the group consisting of Li, Na, K, Cs and Rb,

M²⁺ is at least one member selected from the group consisting of Be, Mg, Ca, Sr, Ba, Zn, Cd, Cu, Pb and Ni,

M³⁺ is at least one member selected from the group consisting of Sc, Y, La, Ce, Pr, Nd, Pm, Sm, Eu, Gd, Tb, Dy, Ho, Er, Tm, Yb, Lu, Al, Bi, In and Ga,

Z is at least one member selected from the group Ga¹⁺, Ge²⁺, Sn²⁺, Sb³⁺ and As³⁺,

X, X′ and X″ may be the same or different and each represents a halogen atom selected from the group consisting of F, Br, Cl, and I, and 0≦a≦1, 0≦b≦1 and 0<c≦0.2.

In the method of manufacturing a radiation image storage phosphor layer on a support or substrate in a vapor deposition apparatus according to the present invention, said method thus comprises a vapor depositing step of raw materials of an alkali metal halide salt and a lanthanide dopant salt or a combination thereof in order to ensure vapor deposition of a binderless needle-shaped storage phosphor layer, wherein a ratio between the total surface of perforations in said inner lid more close to the bottom of crucible and the total surface of perforations in said outer lid more close to the support is not more than 1.0. More particularly, according to the method of the present invention, it is advantageous that said ratio is not more than 0.50, and even more advantageous that said ratio is not more than 0.30. In one embodiment according to the method of the present invention, before starting evaporation said crucible is additionally covered with a non-perforated cover as a closing cover, while heating raw materials present in said crucible up to a starting temperature allowing vaporization. It is moreover advantageous according to the method of the present invention to provide a step wherein during evaporation an additional heating is applied within the space between both said inner (second) and said outer (first) perforated lidas already suggested hereinbefore. In the method according to the present invention it is further recommended that the said method comprises a step wherein a vapor deposition rate is in the range from 0.3 to 3 mg/cm²·min.

Particular screens or panels, and, more particularly those having phosphor or scintillator layers composed of alkali metal halides as a matrix compound and a lanthanide as a dopant or activator compound, are manufactured in a vapor deposition apparatus according to the present invention, and, more particularly a phosphor screen or panel containing a CsX:Eu stimulable phosphor, wherein X represents a halide selected from the group consisting of Br and Cl, is advantageously manufactured therein.

In favor of X-ray resistance of the storage phosphor plate, it may be advantageous to add salts differing from the main component CsBr to the raw materials in the crucible. Addition e.g. of Na- or Rb-salts as “impurities” in a in an amount in the range from about 5 up to 100 p.p.m., and more preferably up to 25 p.p.m., may be advantageous. Optional presence of fluoride ions or organic solvent gases therefrom, more particularly at the surface of the needles formed, may be in favor of moisture resistance and may thus avoid loss in luminance.

Preparation steps in order to manufacture such screens or panels have been described in U.S. Pat. No. 6,802,991. In favor of image sharpness needle shaped Eu-activated alkali metal halide phosphors, and more particularly, Eu-activated CsBr phosphor screens as described in US-A 2003/0091729 are preferred and, in view of an improved sensitivity, annealing of said phosphors as in U.S. Pat. No. 6,730,243 is advantageously performed, said annealing step consisting of bringing the cooled deposited mixture as deposited on the substrate to a temperature between 80 and 220° C. and maintaining it at that temperature for between 10 minutes and 15 hours. Such an annealing step may proceed in an ambient or in an inert atmosphere. After annealing heat-sealing of the phosphor panel between two resin films such as e.g. plastic film, such as a cellulose a cetate film, polyester film, polyethylene terephthalate, a polyamide film, a polyimide film, a triacetate film, and a polycarbonate film; even between sheet glass such as e.g. a quartz, boro-silicated glass, and chemical tempered glass, or an enveloping film of metal sheets such as aluminum, iron, copper, and chromium or oxides thereof, may be applied.

The high degree of crystallinity of needle-shaped phosphor layers is easily analysed by X-ray diffraction techniques, providing a particular XRD-spectrum as has been illustrated in US-A 2001/0007352 and the corresponding EP-A 1 113 458.

As an alkali metal halide salt use is advantageously made of CsBr, wherein, as a lanthanide dopant salt use is made of EuX₂, EuX₃, EUOX or EuX_{z}, wherein 2<z<3. In one embodiment a mixture of CsBr and EuOBr and/or EuBr₃ is provided as a raw material mixture in the crucibles, wherein a ratio between both raw materials normally is about 90% of the cheap CsBr and 10% of the expensive EuOBr, both expressed as weight %.

In another embodiment a combination of an alkali metal halide salt and a lanthanide dopant salt use is further advantageously made of a salt according to the formula CsₓEu_{y}X′_{x+αy}, wherein x/y>0.25, wherein α≧2 and wherein X′ is a halide selected from the group consisting of Cl, Br and I and combinations thereof.

In the vapor deposition apparatus according to the present invention a pressure is normally maintained in the range from 10⁻⁵ to 1 Pa, throughout the vapor deposition process.

Taking into account the measures to be taken in the vapor deposition apparatus according to the present invention, higher amounts of Europium dopant, e.g. in the range from at least 500-800 p.p.m., are attainable, moreover showing an improved homogeneity, in that europium dopant is more homogeneously divided over the needle volume and in that screens or panels having higher dopant amounts thus become available, without the danger of having disturbing, undesired interstitial needle growth, thanks to a sufficiently high concentration gradient of supplied vaporized raw material. Apart from an increased speed, an improved sharpness is obtained by the measures taken in the cover assembly according to the present invention. Any measure may further be taken in order to make increase speed to the desired level, as e.g., by annealing with heat or radiation as has e.g. been described in U.S. Pat. Nos. 6,730,243 and 7,126,135, or as described in Ser. No. 11/855,499.

In favor of having a flat needle phosphor layer surface, a polishing step may be applied as described in U.S. Pat. No. 6,936,304, optionally followed by removal of fine phosphor powder particles present after said polishing step, by blowing of a (preferably dry) gas against the stimulable phosphor layer in its width direction and a suction means adjoining to the gas blowing means in parallel with the width direction of the gas blowing means. Polishing by sand blasting may also be applied.

In favor of protection against aging and deterioration by moisture, the vapor deposited phosphor layer is protected by a protective layer, as e.g. a parylene layer, whether or not coated thereupon by a vapor deposition process as described in U.S. Pat. No. 6,710,356 or in form of a transfer foil, i.e. by a laminating process, as described e.g. in U.S. Pat. No. 7,141,135. A laminate in form of glass as in U.S. Pat. Nos. 5,871,879; 6,287,274; 6,299,754; 6,306,510 and 6,366,013 may also be applied. Lamination may proceed in batch, i.e. plate after plate, or in a continuous on-going preparation process, i.e. on roll as disclosed more particularly in U.S. Pat. No. 7,141,135. Top coating by a laminate may further be in favor of sharpness as within the tops of the needles cross-talk becomes avoided as no material differing from the raw materials, e.g. in form of an organic or inorganic polymer, partially penetrates into the space between the said needles. A further advantage of a laminate layer is related with the recovering of the phosphor after a long time of use in practice: when e.g. an adhesive member is placed between part of the surface of the panel outside the image-forming area or part of the surface of the support and the protective laminate foil in favor of protection against moisture, it will be easier to recover the phosphor as no adhesive is present in the largest part of the phosphor layer. Apart from making use of an adhesive in favor of good adhesion between phosphor layer and laminated protective layer, a plasma treatment of the surface of the phosphor layer may be applied. It is clear that all measures wherein flatness of the phosphor layer (e.g. by polishing, plasma treatment, etc.) and of the laminated protective layer at the contact side with the phosphor layer are strived at, are in favor of a reduction of screen structure noise in the image obtained after exposure and read-out of the storage phosphor plate.

In a further embodiment the peripheral part of the protective layer and of the support is chamfered in order to provide protection against mechanical damage, due to frequent use of the storage phosphor panel as a consequence of transport in and from an exposure unit to and in a scanning read-out unit.

Other protective layers may also be applied if desired, as e.g. those described in U.S. Pat. Nos. 6,800,362; 6,822,243; 6,844,056; 7,091,501 and 7,193,226 as well as those described in US-Applications 2004/0164251 and 2004/0228963. A polyurea protective film may be formed on the phosphor layer, making use of an amine compound and an isocyanate compound either of which is an aliphatic compound. The protective layer may even contain ultraviolet absorbing compounds or, alternatively, may include an alumina-evaporated layer.

Roughness of the protective layer may be adapted to transport requirements in a scanner and read-out apparatus used in the image formation step.

Multiple overcoat layers may moreover be provided, in order, as a most important condition, to reduce moisture absorption up to a level of much less than 0.5 ml per square meter and per 24 hours at an ambient temperature of 25° C., e.g. by making use of a so-called nano-structure control film wherein several thousands layers are laminated in one thin film with a thickness per layer of several nm to several tens nm is adhered to a phosphor layer.

It is advantageous to provide protection against dust onto the support before starting and ending evaporation, and after having coated or laminated a protective layer onto the phosphor layer. Besides use of mechanical means as e.g. a set of brushes, direct lamination with a (temporary) foil is advantageous, more particularly if no dust free room is available. In favor of avoiding electrostatic attraction of dust by polymeric foils, an antistatic foil may be provided, such as e.g. polyethylene-dioxy-thiophene (PEDT). In another embodiment a dust removal adhesive layer as a temporarily layer may be applied to the protective layer and removed in order to remove undesired dust or dirt particles.

Making use of more than one crucible, at least one of which has, or, more preferred, both of them have the desired configuration as described hereinbefore may provide as an advantage that both crucibles act independently in the vaporization process, which may be in favor of vaporization and deposition control when both crucibles are filled with compositions differing in composition and vapor pressure at high vaporization temperatures, as, e.g. one with a predominant or even an exclusive amount of main, parent or matrix compound as e.g. CsBr, whereas the other one is filled with a predominant or even an exclusive amount of dopant as e.g. EuOBr. In another embodiment one crucible, e.g. the crucible with the raw material providing the dopant or activator, may be located more close to the support.

Another advantage offered by making use of more than one crucible as set forth hereinbefore is e.g. when more than one needle-shaped layer is desired, wherein each layer thereof may have the same or a different composition and wherein subsequent depositions may proceed within a time period between removing and covering the respective slot covers from the respective crucibles.

Storage phosphor plates having an aluminum support can be cut into the desired formats by making use of accurate and very rapid sawing machines, working at high velocities, as e.g. at least 30,000 r.p.m., available e.g. from Komec-Helsen, Wilrijk, Belgium.

While the present invention will hereinafter in the examples be described in connection with preferred embodiments thereof, it will be understood that it is not intended to limit the invention to those embodiments.

### EXAMPLES

In a vapor deposition apparatus a rectangular boat or crucible (2) having as dimensions 15 cm in its length direction, 3.5 cm in its width direction and 4.75 cm in its height direction was fold from a refractory material plate of tantalum, delivered by H. C. Starck, Liaison Office Benelux, Mijdrecht, The Netherlands.

The crucible (1) thus folded, was provided with notches and perforations as set out in US-A 2006/0013966 in order to get the resistively heated crucible to be heated in a homogeneous way as presence of notches and perforations avoids cooling by the clamps, thanks to passage of equal amounts of energy in form of electrical power through a smaller crucible section, thereby reducing mass effects to a considerable extent.

The first or outer lid was covering the crucible on top (position: 0), while the second or inner lid was more close to the bottom as positioned 15 mm under the first lid or cover.

In order to connect the crucible and the electrodes required for resistive heating of the crucible, the crucible had a lip (3) with a length of 20 mm and a width of 35 mm at both sides of the crucible. The crucible (1) was covered with a closing cover plate (4) without openings, having as dimensions 60 mm×200 mm, covering the crucible as long as vapor deposition was not started, while heating the raw materials in the crucible up to the desired temperature before effectively starting vaporization.

Numbers of splits or openings, as well as dimensions of the said splits or openings of the inner lids or perforated covers (5) and (6) have been given in the Table 1. Perforated cover (5) is called herein “outer lid” or cover more close to the support or substrate, while perforated cover (6) represents the “inner lid” or cover more close to the bottom of the crucible. Dimensions of the openings in the perforated covers (5) and (6) are related with the width of the split or the (equivalent circular) diameter of an opening, as well as with the total surface of the openings.

It is clear that the first condition, i.e. to have “no overlap” between perforations was ever fulfilled, in that from any point of the support or substrate, it was impossible to observe the bottom of the crucible or boat, nor the surface of the raw materials through the openings of the perforated inner lids or covers in the crucible assembly.

Moreover as an important steering parameter the temperature of the crucible as measured by thermocouples, protected with a tantalum cover, has been given: one figure in the Table 1 is related with the temperature measured in the bulk of the raw materials present on the bottom of the crucible (T_{bulk}), the other is related with the temperature measured in the part of the boat, between the position of the two perforated inner lids or covers (T_{fold}). As a third controlled temperature, the temperature at the back side of the mounted anodized aluminum substrate was measured by means of a thermocouple. Dimensions for that substrate were 104 mm×104 mm×0.8 mm.

TABLE 1

| | | | | Inner | Outer | | | | | |
|---|---|---|---|---|---|---|---|---|---|---|
| | | | | 2^{nd} lid | 1^{st} lid | Openings | Vaporization | | | |
| | | Split | Opening | openings | openings | surface ratio | time | | | |
| CB | No | width | diameter | surface | surface | 2^{nd}/1^{st} | in | T_{bulk} | T_{fold} | T_{back} |
| No. | of splits | (mm) | (mm) | (mm²) | (mm²) | cover | min. | (° C.) | (° C.) | (° C.) |
| 24710 | 2 | 6.5 | — | 1235 | 907 | 1.36 | 20 | 710 | 860 | 159.8 |
| (comp.) | | | | | | | | | | |
| 24711 | 1 | 35 | — | 3325 | 907 | 3.67 | 15 | 717 | 996 | 168 |
| (comp.) | | | | | | | | | | |
| 24802 | 17 | — | 3 | 120 | 907 | 0.13 | 125 | 722 | 748 | 168 |
| (inv.) | | | | | | | | | | |
| 24803 | 17 | — | 4 | 214 | 907 | 0.24 | 70 | 730 | 770 | 159.4 |
| (inv.) | | | | | | | | | | |
| 24805 | 2 | 4 | — | 760 | 907 | 0.84 | 25 | 731 | 906 | 156.3 |
| (inv.) | | | | | | | | | | |
| 24806 | 35 | — | 3 | 247 | 907 | 0.27 | 60 | 714 | 735 | 156.8 |
| (inv.) | | | | | | | | | | |
| 24807 | 17 | — | 2 | 53 | 907 | 0.06 | 185 | 721 | 726 | 150.3 |
| (inv.) | | | | | | | | | | |

CsBr:Eu screens were prepared in a thermal vapor deposition process, starting from CsBr and EuOBr as raw materials for matrix and dopant or activator respectively. Therefor 330 g of CsBr was mixed with EuOBr in an amount of 0.5% by weight versus the main or matrix CsBr component and the mixture was added to the crucible in the a vapor deposition chamber of the vapor deposition apparatus, before mounting the two subsequent perforated lids or covers.

The distance between the highest point of the container and the aluminum substrate was set at 195 mm.

During evaporation, the anodized aluminum support was mounted against a substrate holder. The support was heated by means of lamps to a temperature of 160° C.

The container with starting materials was heated to a temperature of 720±11° C. Before the start of the evaporation, the vaporization chamber was evacuated to a pressure of 4 mPa. During the evaporation process, Ar was introduced in the chamber at a pressure between 1.0 and 2.5 Pa.

Thanks to the presence of notches in the cross-section region of the upper lips between side wall and electrode clamp of the crucible, wherein moreover each lip was provided with perforations, such a crucible was heated more homogeneously as at the clamping site, between clamp parts, the temperature was lower than for all other sites of the crucible, once the process of evaporation of raw materials started.

This was moreover the case when an equilibrium was reached and a homogeneous heating of the crucible appeared, as well as a homogeneous deposit of evaporated raw materials. Moreover a decreased risk for “spitting” of the liquefied raw materials was observed.

In the vapor deposition apparatus of the present invention the crucible was heated to an optimized and constant high temperature, while covering the assembly with the non-perforated outermost closing or slot cover, in order to get said temperature homogeneously distributed over the whole crucible in order to further liquefy and evaporate the raw materials (CsBr and EuOBr) in a “steady-state-flow” in a homogeneous vapor cloud after removal of the said outermost non-perforated cover.

After deposition of the phosphor layer and after cooling, an annealing procedure was performed by heating the layer to a temperature of 170° C. during a time of 4 hours.

Between the preparation of each of the screens or panels, the crucible was cleaned by a washing procedure, followed by firing procedure. So before starting a new vapor deposition process from raw materials by depositing said raw materials in vaporized form in a vapor deposition apparatus comprising a crucible as in the present invention were provided with refreshed surfaces.

Cleaning, optionally performed with aqueous or non-aqueous solutions and further combined with an ultrasonic treatment, was not required within the series of experiments as performed now in order to renew or replace the crucible, one or more covers or corroded parts composed of refractory material.

A CsBr:Eu stimulable phosphor layer having a coverage or coating weight, expressed in mg/cm² as indicated in the Table 2, was deposited onto the support. Moreover, the Eu-dopant amount, expressed in mg/kg (p.p.m.), as analyzed after deposition of the phosphor layer, has been given in that Table 2.

The sensitivity of the screen was further measured in the following way: the screen was homogeneously exposed with a dose of ca. 50 mR at 80 kVp. Read-out was done with a flying spot scanner.

In the scanner, the scanning light source was a 30 mW diode laser emitting at 685 nm. A 3-mm BG-39 (trade name of Schott) filter coated at both sides with a dielectrical layer was used in order to efficiently separate the stimulation light from the screen emission light.

The scan-average level (SAL) was determined as the average signal produced by the screen field in the photomultiplier tube. This average signal was compared with the signal generated by an Agfa powder imaging plate. The sensitivity, expressed in % compared with the reference Agfa powder imaging plate was obtained, has been given in the Table 2.

Last but not least, image sharpness expressed as MTF at 1 lp/mm and 3 lp/mm has further been measured and figures thereof have been given in the Table 2 hereinafter.

TABLE 2

| | Coating | | | | Eu dopant | |
|---|---|---|---|---|---|---|
| | weight | SAL % | MTF | MTF | amount | Spitting |
| CB-No. | (mg/cm²) | (annealed) | 1 lp/mm | 3 lp/mm | (p.p.m.) | errors |
| 24710 | 146.0 | 522 | 0.45 | 0.11 | 294 | — |
| 24711 | 140.0 | 477 | 0.45 | 0.11 | 154 | — |
| 24802 | 110.4 | 521 | 0.58 | 0.15 | 406 | — |
| 24803 | 128.3 | 540 | 0.55 | 0.13 | 260 | — |
| 24805 | 163.1 | 580 | 0.47 | 0.12 | 312 | — |
| 24806 | 136.4 | 497 | 0.55 | 0.13 | 287 | — |
| 24807 | 82.5 | 361 | 0.64 | 0.19 | 363 | — |

From the data in that Table 2 it is concluded that unexpectedly low vapor deposition rates of even less than 1 mg/cm².min. provide excellent results with respect to sharpness, opposite to the disclosures in U.S. Pat. No. 6,720,026 and US-Application 2005/0077478, wherein a deposition rate of more than 1 mg/cm².min. is recommended.

By making use of a perforated cover assembly in a vapor deposition apparatus according to the present invention not only “spitting” or formation of undesired spots becomes avoided as envisaged in the objects of the present invention, but a more homogeneous distribution of the dopant becomes available, even if said dopant is present in higher amounts—i.e. in higher concentrations as for the needle-shaped CsBr:Eu phosphor, having divalent Eu as an activator or dopant, eventually comprising trivalent Eu in minor amounts.

As an advantageous effect of the present invention the slower deposit of the formed phosphor needles from the raw materials present in the crucible, not only allows presence in higher amounts of a more homogeneously distributed dopant or activator in the phosphor, thereby providing a higher speed to the panel, but moreover allows a better separation between the needles, less cross-talk and a better image definition or sharpness, thanks to a better steered, about constant temperature of the support, whereupon the phosphor needles become vapor deposited.

Thanks to differences in pressures built up between the surface of liquefied raw material present in the crucible and the perforated cover more close to those raw materials, between that perforated cover and the perforated outer cover more close to the support, and in the space between crucible and support, temperature increases of the substrate while vapor depositing vaporized raw material are avoided, thus providing more uniform needle growth without undesired interstitial growth phenomena and moreover providing an improved sharpness.

Inhibition of direct seeing of the raw material present at the bottom of the crucible from any point of the substrate through the perforations moreover avoids deposit of undesired spots of raw material onto the vapor deposited phosphor or scintillator layer.

Although the present invention has been described in connection with preferred embodiments thereof, it will be understood that it is not intended to limit the invention to those embodiments, as it is apparent to those skilled in the art that numerous modifications can be made, e.g. by making use of more than one crucible having the desired configuration as described hereinbefore, without departing from the scope of the invention as defined in the appending claims.

### PARTS LIST

(1) folded tantalum crucible
(2) container of the crucible
(3) lip (present at both sides of the crucible)
(4) cover plate without perforations, but provided with a slit (5)
(5) slit in cover plate (4) without further perforations.
(6) guiding plate, guiding vapor in a direction to the support
(7) folded perforated inner cover plate more close to the bottom
(8) folded perforated outer cover plate more close to the support.

What is claimed is:

1. A vapor deposition apparatus comprising as a vaporization assembly a container in form of a boat or crucible having a bottom and side walls, and a support or substrate for vapor depositing phosphor or scintillator material in form of a layer thereupon, from vaporized raw materials present in said container, wherein said container internally comprises an assembly of at least two covers or lids having one or more perforations, one of which is an outer lid as a first lid more close to the said support and the other cover is an inner lid as a second lid more close to the bottom of the said boat or crucible; wherein perforations present in said outer lid represent a total surface exceeding the total surface of perforations present in said inner lid more close to the bottom of the said boat or crucible, and wherein in said vapor deposition apparatus said raw materials or the bottom of the said crucible can never be directly seen through said perforations from any point of said support.

2. Vapor deposition apparatus according to claim 1, wherein every distance between said inner and said outer lid is feasible, and wherein the second or inner lid, more close to the bottom of the crucible, is not positioned into the liquefied raw materials.

3. Vapor deposition apparatus according to claim 1, wherein every distance between said inner and said outer lid is feasible, and wherein the second or inner lid more close to the bottom of the crucible, when positioned into the liquefied raw materials, does not remain positioned into the said liquefied raw materials for a period of time of more than 50% of the total evaporation time.

4. Vapor deposition apparatus according to claim 1, wherein perforations in said inner and said outer lid have equivalent circular diameters in the range of 1 mm up to 5 mm, with an average distance between centers of the said holes in the range from 2 mm up to 10 mm.

5. Vapor deposition apparatus according to claim 1, wherein said inner and said outer lid are mounted parallel versus each other in said container.

6. Vapor deposition apparatus according to claim 1, wherein said assembly of two covers or lids and said crucible are composed of the same or differing refractory materials, and wherein said refractory materials are metal or metal alloys selected from the group consisting of tantalum (Ta), molybdenum (Mo), niobium (Nb), tungsten (w) and heat-resistant stainless steel.

7. Method of manufacturing a radiation image storage phosphor layer on a support or substrate, said method comprising a vapor depositing step of raw materials of an alkali metal halide salt and a lanthanide dopant salt or a combination thereof in order to ensure vapor deposition of a binderless needle-shaped storage phosphor layer in a vapor deposition apparatus according to claim 1, wherein a ratio between the total surface of perforations in said inner lid more close to the bottom of crucible and the total surface of perforations in said outer lid more close to the support is not more than 1.0.

8. Method according to claim 7, wherein before starting evaporation, said crucible is additionally covered with a non-perforated cover as a closing cover, while heating raw materials present in said crucible up to a starting temperature allowing vaporization.

9. Method according to claim 7, comprising a step wherein during evaporation an additional heating is applied within the space between said inner and said outer lid.

10. Method according to claim 7, comprising a step wherein a vapor deposition rate is in the range from 0.3 to 3 mg/cm²·min.
